(19) United States
(12) Patent Application Publication
(10) Pub. No.: US 2026/0153568 A1
(43) Pub. Date: Jun. 4, 2026

(54) METHOD AND APPARATUS WITH BATTERY SHORT CIRCUIT DETECTION

(71) Applicant: Samsung Electronics Co., Ltd., Suwon-si (KR)

(72) Inventors: Myeongjae LEE, Suwon-si (KR); Jinho KIM, Suwon-si (KR); Terrance Christopher HUANG, Suwon-si (KR)

(73) Assignee: Samsung Electronics Co., Ltd., Suwon-si (KR)

(21) Appl. No.: 19/316,266

(22) Filed: Sep. 2, 2025

(30) Foreign Application Priority Data
Dec. 3, 2024 (KR) 10-2024-0177827

(51) Int. Cl. G01R 31/392; G01R 31/36; G01R 31/367; G01R 31/388; G01R 31/52; H01M 10/44

(52) U.S. Cl. CPC G01R 31/392; G01R 31/3648; G01R 31/367; G01R 31/388; G01R 31/52; H01M 10/44

(57) ABSTRACT

A method and apparatus with short circuit detection are provided. The method includes generating measurement data by measuring a state of a battery; generating estimation data regarding the state of the battery using a battery model that simulates the battery; determining, using the measurement data and the estimation data, detection parameters for detecting a short circuit in the battery; detecting short circuit feature signals based on the detection parameters; determining a processed score by processing detection scores assigned to the short circuit feature signals according to types of the short circuit feature signals; and determining a current short circuit level among multiple predefined short circuit levels based on the processed score.

### CROSS-REFERENCE TO RELATED APPLICATIONS

This application claims the benefit under 35 USC § 119(a) of Korean Patent Application No. 10-2024-0177827, filed on Dec. 3, 2024, in the Korean Intellectual Property Office, the entire disclosure of which is incorporated herein by reference for all purposes.

### BACKGROUND

### 1. Field

The following description relates to a method and apparatus with battery short circuit detection.

### 2. Description of Related Art

A battery short circuit not only deteriorates battery efficiency but also serves as a primary cause of thermal runaway, posing serious safety risks such as battery explosions. Thus, ensuring battery safety by effectively detecting a short circuit before significant physical or thermal deformation occurs is critical. Typically, battery short circuits are detected by monitoring changes in current, voltage, capacity, or temperature of the battery, as well as variations in parameters within an electric circuit model. In addition, for multi-cell battery packs, detection methods uses various deviations among individual unit cells to identify potential short circuits.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method includes generating measurement data by measuring a state of a battery; generating estimation data regarding the state of the battery using a battery model that simulates the battery; determining, using the measurement data and the estimation data, detection parameters for detecting a short circuit in the battery; detecting short circuit feature signals based on the detection parameters; determining a processed score by processing detection scores assigned to the short circuit feature signals according to types of the short circuit feature signals; and determining a current short circuit level among multiple predefined short circuit levels based on the processed score.

The processed score may include at least one of an accumulated score of the detection scores or a moving average of the detection scores.

In the method, different detection scores are assigned to different types of the short circuit feature signals, wherein the different detection scores are set based on at least one of sensitivity of the battery to the short circuit or an influence of the respective short circuit feature signal on the short circuit.

The method may further include setting the current short circuit level to a higher level that is closer to a confirmed short circuit state, when a level increase condition is satisfied.

The level increase condition may be set based on the processed score exceeding a corresponding threshold value.

The method may further include setting the current short circuit level to a lower level that is closer to a normal state when a level decrease condition is satisfied.

The level decrease condition may be set based on a degree to which a stable state is maintained by the battery.

The stable state may be defined as a state in which no additional short circuit feature signals are detected over a predetermined period.

In the method, each of the short circuit levels may be associated with one of three states, comprising a normal state in which the battery operates without the short circuit, a suspicious state in which the short circuit may be suspected to occur, and a short circuit state indicating that the short circuit is confirmed, wherein the level decrease condition may be applied only to levels corresponding to the normal and suspicious states.

The detection parameters may include a charging and discharging capacity error parameter representing a difference between a discharging capacity and a charging capacity measured over a first target section, spanning from a first target point in a discharging phase where the battery reaches a reference charging capacity to a second target point in a charging phase where the battery reaches the reference charging capacity again, wherein the short circuit feature signals comprise a first short circuit feature signal generated by comparing the charging and discharging capacity error parameter with a corresponding threshold value.

The detection parameters may include an accumulated state of charge (SOC) correction parameter representing an accumulated SOC correction value in a second target section between a third target point in a discharging phase where the battery reaches a reference SOC and a fourth target point in a charging phase where the battery reaches the reference SOC again, wherein the short circuit feature signals comprise a second short circuit feature signal generated by comparing the accumulated SOC correction parameter with a corresponding threshold value.

The measurement data may include a measurement voltage and a measurement current, the estimation data may include an estimation voltage, and wherein the detection parameters comprise a resistance error parameter representing a ratio between the measurement current and a voltage error corresponding to a difference between the measurement voltage and the estimation voltage, and an average resistance error difference parameter representing a difference between a first average resistance error of a third target section in a discharging phase and a second average resistance error of a fourth target section in a charging phase, and wherein the short circuit feature signals comprise a third short circuit feature signal generated by comparing the average resistance error difference parameter with a corresponding threshold value.

The detection parameters may include an accumulated state of charge (SOC) correction difference parameter representing a difference between accumulated SOC correction values of target points in a constant voltage (CV) charging section, wherein the short circuit feature signals may include a fourth short circuit feature signal generated by comparing the accumulated SOC correction difference parameter with a corresponding threshold value.

In one general aspect, an apparatus includes one or more processors respectively comprising processing circuitry; and a memory storing executable code, which upon execution by the one or more processors, configures the one or more processors to: generate measurement data by measuring a state of a battery; generate estimation data regarding the state of the battery using a battery model that simulates the battery; determine, using the measurement data and the estimation data, detection parameters for detecting a short circuit of the battery; detect short circuit feature signals based on the detection parameters; determine a processed score by processing detection scores assigned to the short circuit feature signals according to types of the short circuit feature signals, ; and determine a current short circuit level among multiple predefined short circuit levels based on the processed score.

The processed score may include at least one of an accumulated score of the detection scores or a moving average of the detection scores.

The one or more processors may be further configured to set the current short circuit level to a higher level that is closer to a short circuit state when a level increase condition is satisfied.

The one or more processors may be further configured to set the current short circuit level to a lower level that is closer to a normal state when a level decrease condition is satisfied, wherein the level decrease condition is set based on a degree to which a stable state is maintained by the battery.

In one general aspect, an electronic device includes a battery configured to supply power to the electronic device; and one or more processors, wherein the one or more processors are configured to generate measurement data by measuring a state of the battery; generate estimation data regarding the state of the battery using a battery model that simulates the battery; determine, using the measurement data and the estimation data, detection parameters for detecting a short circuit of the battery; detect short circuit feature signals based on the detection parameters; determine a processed score by processing detection scores assigned to the short circuit feature signals according to types of the short circuit feature signals, ; and determine a current short circuit level among multiple predefined short circuit levels based on the processed score.

Other features and aspects will be apparent from the following detailed description, the drawings, and the claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a configuration and operation of a short circuit detection apparatus according to one or more embodiments.

FIG. 2 illustrates an operation of generating detection parameters, short circuit feature signals, detection scores, and a processed score according to one or more embodiments.

FIG. 3 illustrates short circuit levels according to one or more embodiments.

FIG. 4 illustrates an operation of determining a charging and discharging capacity error parameter according to one or more embodiments.

FIG. 5 illustrates an operation of determining an accumulated state of charge (SOC) correction parameter according to one or more embodiments.

FIG. 6 illustrates an operation of determining an average resistance error parameter according to one or more embodiments.

FIG. 7 illustrates an operation of determining a resistance error change rate parameter according to one or more embodiments.

FIG. 8 illustrates an operation of determining an accumulated SOC correction difference parameter in a constant voltage (CV) charging section according to one or more embodiments.

FIG. 9 illustrates an operation of adjusting a current short circuit level according to one or more embodiments.

FIG. 10 illustrates another operation of adjusting a current short circuit level according to one or more embodiments.

FIG. 11 illustrates a configuration of a short circuit detection apparatus according to one or more embodiments.

FIG. 12 illustrates a configuration of an electronic device according to one or more embodiments.

FIG. 13 illustrates a short circuit detection method according to one or more embodiments.

Throughout the drawings and the detailed description, unless otherwise described or provided, the same or like drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” to specify the presence of stated features, numbers, operations, members, elements, and/or combinations thereof, other embodiments may exist where one or more of the stated features, numbers, operations, members, elements, and/or combinations thereof are not present.

Throughout the specification, when a component, element, or layer is described as “on,” “connected to,” “coupled to,” or “joined to” another component, element, or layer, it may be directly (e.g., in contact with the other component, element, or layer) “on,” “connected to,” “coupled to,” or “joined to” the other component, element, or layer, or there may reasonably be one or more other components, elements, or layers intervening therebetween. When a component, element, or layer is described as “directly on,” “directly connected to,” “directly coupled to,” or “directly joined to” another component, element, or layer, there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment,” and “one or more examples” has a same meaning as “in one or more embodiments”).

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

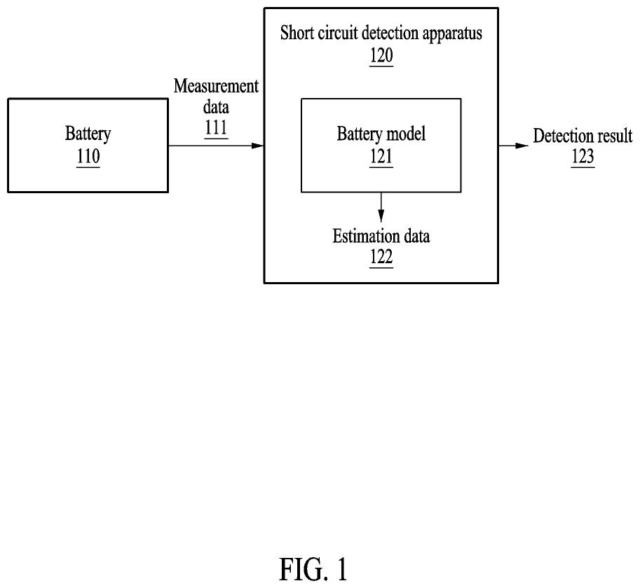

FIG. 1 illustrates a configuration and operation of a short circuit detection apparatus according to one or more embodiments.

A battery short circuit may deteriorate/degrade the energy efficiency of a battery and may cause serious safety hazards, such as being a primary cause of thermal runaway of the battery. It is therefore essential to detect short circuits at a micro-short circuit level in the initial stage where safety measures are still feasible. In the case of a battery micro-short circuit, the change in a battery signal (e.g., current, voltage, temperature, etc.) due to the occurrence of a short circuit may be extremely small. Because it is difficult to detect the influence of extremely small micro-short circuit current compared to the battery charging current under a high-rate charging condition while driving a battery, typical methods tend to detect a larger short circuit than a micro-short circuit or to detect a battery rest state, making it difficult to effectively distinguish a short circuit from normal variations due to driving conditions, temperature fluctuations, or battery deterioration.

Technology employing artificial intelligence (AI), such as machine learning, may determine battery short circuits by analyzing differences or changes in various parameters. However, the detection accuracy and sensitivity to micro-short circuits may vary significantly depending on the accuracy of a model, and may be limited by factors such as high-rate driving, battery deterioration, measurement errors, etc. In addition, integrating AI technology may require increased computing power.

Referring to FIG. 1, a short circuit detection apparatus 120 (hereinafter referred to as ‘apparatus 120’) may output a detection result 123 regarding a battery short circuit based on measurement data 111. A battery 110 may include a single battery cell or multiple battery cells, any of which may experience a short circuit. The measurement data 111 may include data/information associated with the specification and/or operations of the battery 110 monitored by the apparatus 120. For example, during the battery 110 being charged, the measurement data 111 may include charging signals of the battery 110, and during the battery 110 being discharged, the measurement data 111 may include discharging signals of the battery 110. These battery signals may include voltage, current, temperature, etc., of the battery 110. The measurement data 111 may be measured and obtained by various sensors located inside and/or outside the battery 110. The detection result 123 may include short circuit information such as whether a short circuit is detected, the detection time of a short circuit, the duration of a short circuit, and the intensity of a short circuit. Based on the detection result 123, appropriate countermeasures may be performed on the short circuit. For example, when a short circuit of the battery 110 is definitively detected, an alarm may be provided to a user based on the detection result 123.

The apparatus 120 may estimate a state (e.g., a state of charge (SOC), voltage, etc.) of the battery 110 using a battery model 121 that simulates behaviors of the battery 110, thereby generating estimation data 122. The battery model 121 may be an electrochemical thermal (ECT) model that simulates an internal state of the battery 110 using various ECT parameters and governing equations. For example, the parameters of the ECT model may represent the battery's physical dimensions (e.g., thickness, radius, etc.), open circuit potential (OCP), and physical properties (e.g., electrical conductivity, ionic conductivity, diffusion coefficients, etc.). The governing equations may include an electrochemical reaction occurring at the interface between an electrode and an electrolyte based on these parameters, and a physical preservation equation related to the concentration and conservation of charge of the electrode and the electrolyte.

The ECT model may estimate the state of the battery 110 based on the measurement data 111. For example, the ECT model may estimate an SOC and voltage of the battery 110 based on measured current and temperature of the battery 110 according to the measurement data 111. The apparatus 120 may detect a short circuit state using/analyzing an error between the measurement data 111 measured by the battery 110 and the estimation data 122 estimated through the battery model 121. The error may be referred to as an estimation error. The battery model 121 may further include an error correction model that corrects the estimation data 122 to reduce the estimation error. For example, the error correction model may adjust a voltage estimation value and/or an SOC estimation value such that a voltage estimation error between a voltage measurement value and the voltage estimation value is reduced. As the error increases, the correction value may increase. The apparatus 120 may use changes in the correction value and/or the estimation error during a predetermined time period to detect a short circuit.

The apparatus 120 may determine, using both the measurement data 111 and the estimation data 122, detection parameters for identifying/detecting a short circuit in the battery 110. For example, the detection parameters may be determined, but are not limited thereto, based on a voltage error, a resistance error, an SOC error, a capacity error, an accumulated voltage error, an accumulated resistance error, an accumulated SOC error, an accumulated capacity error, a voltage error change, a resistance error change, an SOC error change, a capacity error change, etc. The error may be corrected by the error correction model. In this context, the error may refer to a correction value provided by the error correction model. The error change may occur between a first point and a second point in an operating section including a charging section and a discharging section of the battery 110. For example, the error change may be defined as the difference between a first error at the first point and a second error at the second point. The error change may have a direction (e.g., sign), and the error difference may be the absolute value of the error change. Examples of the detection parameters are described in detail below.

The change in the battery signal (current, voltage, temperature) due to a micro-short circuit is often extremely small, while variations caused by an actual charging and discharging speed, a charging and discharging section (e.g., a voltage section, a time section, a speed range), temperature, an individual battery difference, battery deterioration, etc., may be much larger. This disparity makes it challenging for a typical apparatus to detect short circuits and determine internal short circuit resistance during operation of the battery 110. To overcome this challenge, the apparatus 120 of one or more embodiments may use a high-accuracy battery model 121, which is equipped with features such as a parameter update function and an SOC correction function according to the progress of deterioration, and may perform short circuit detection using various detection parameters. Here, the SOC correction function may maintain the estimation accuracy by adjusting/correcting an SOC state to a predetermined rate/level when a state estimation error of the battery 110 occurs. The parameter update function according to the progress of deterioration may maintain the state estimation accuracy of the battery model 121 even when battery deterioration progresses by updating the parameters of the battery model 121, such as deterioration parameters, to accurate values through a deterioration state estimation.

The apparatus 120 may identify/detect a battery short circuit in stages by defining multiple short circuit levels and determining a current short circuit level among the multiple short circuit levels. When the battery short circuit occurs but is not detected, it may lead to thermal runaway or an explosion. However, when a normal state is incorrectly detected as a short circuit state, other serious problems, such as a recall, etc., may occur. The apparatus 120 of one or more embodiments may minimize the possibility of false detection by detecting the battery short circuit in stages using multiple short circuit levels.

The apparatus 120 may detect feature signals related to a short circuit based on the detection parameters, and based on the types of the feature signals, may determine a processed score by processing detection scores assigned to the short circuit feature signals. For example, the processed score may include, but is not limited thereto, at least one of an accumulated score of the detection scores or a moving average of the detection scores. For example, the moving average and other statistics may be used. The apparatus 120 may determine the current short circuit level among the short circuit levels based on the processed score. The short circuit levels may each belong to one of three states: a normal state in which the battery 110 operates normally without a short circuit, a suspicious state in which the short circuit of the battery 110 is suspected to occur, and a short circuit state in which the short circuit of the battery 110 occurs. The apparatus 120 may declare the short circuit based on the current short circuit level. The short circuit feature signals may be used as clues to detect the short circuit. The apparatus 120 of one or more embodiments may reduce the possibility of false detection of the short circuit by determining the current short circuit level based on the detection scores assigned to the short circuit feature signals rather than immediately declaring the short circuit upon observing the occurrence of the short circuit feature signals.

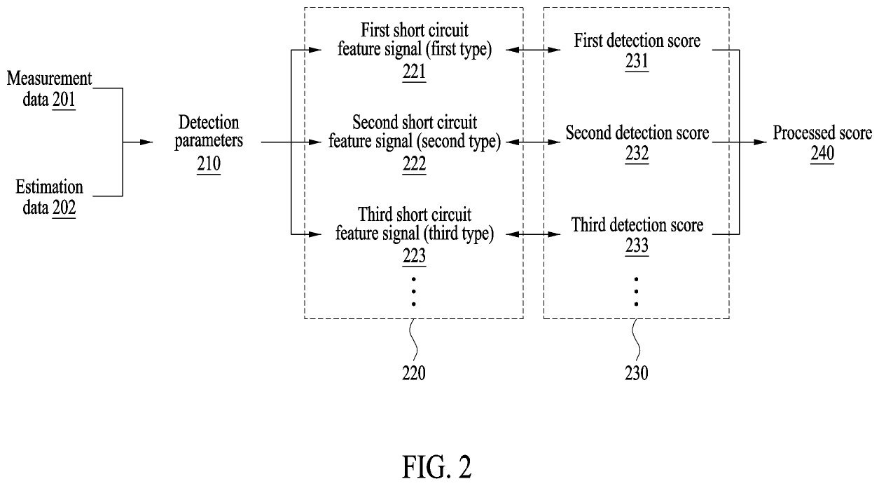

FIG. 2 illustrates an operation of generating detection parameters, short circuit feature signals, detection scores, and a processed score according to one or more embodiments. Referring to FIG. 2, a short circuit detection apparatus (e.g., the apparatus 120 in FIG. 1) may determine detection parameters 210 based on measurement data 201 and estimation data 202. Using the detection parameters 210, the apparatus 120 may identify/detect short circuit feature signals 220 from the measurement data 201 and/or the estimation data 202. Based on the types of the short circuit feature signals 220, the apparatus 120 may determine a processed score 240 by processing detection scores 230 assigned to the short circuit feature signals 220. For example, the processed score 240 may include, but is not limited thereto, at least one of an accumulated score of the detection scores 230 or a moving average of the detection scores 230. The moving average may be an average of a plurality of detection scores acquired based on a plurality of measurement data 201 acquired over a time section when a battery (e.g., the battery 110) is being charged or discharged.

The short circuit feature signals 220 may be categorized into various types, with each type receiving a unique detection score. For example, a first detection score 231 may be assigned to a first short circuit feature signal 221 of a first type, a second detection score 232 may be assigned to a second short circuit feature signal 222 of a second type, and a third detection score 233 may be assigned to a third short circuit feature signal 223 of a third type. Different detection scores among the detection scores 230 may be set or adjusted based on at least one of factors such as the sensitivity of a battery (e.g., the battery 110) to a short circuit and the influence/impact that a particular short circuit feature has on the overall short circuit. For example, the first short circuit feature signal 221 exhibits high sensitivity to the short circuit but exerts minimal influence on the short circuit, whereas the second short circuit feature signal 222 exhibits low sensitivity to the short circuit but exerts a greater influence/impact on the short circuit. In this case, the second detection score 232 of the second short circuit feature signal 222 may be set higher than the first detection score 231 of the first short circuit feature signal 221.

As a non-limiting example, an average resistance error difference parameter and/or a resistance error change rate parameter may be classified as the first type, a charging and discharging capacity error parameter and/or an accumulated SOC correction parameter may be classified as the second type, and an accumulated SOC correction difference parameter may be classified as the third type. In this example, the first detection score 231 of the first short circuit feature signal 221 may be set to 1, the second detection score 232 of the second short circuit feature signal 222 may be set to 5, and the third detection score 233 of the third short circuit feature signal 223 may be set to 7; however, these values are merely illustrative and not intended to be limiting.

Additionally, the detection scores 230 may be set/adjusted based on the frequency of occurrence of the short circuit feature signals 220. When a high detection score is assigned to a feature signal that occurs frequently, an accumulated score may increase rapidly, raising the likelihood/possibility of a false short circuit detection. For example, when a first occurrence frequency of the first short circuit feature signal 221 is higher than a second occurrence frequency of the second short circuit feature signal 222, the first detection score 231 may be set lower than the second detection score 232 to mitigate this risk.

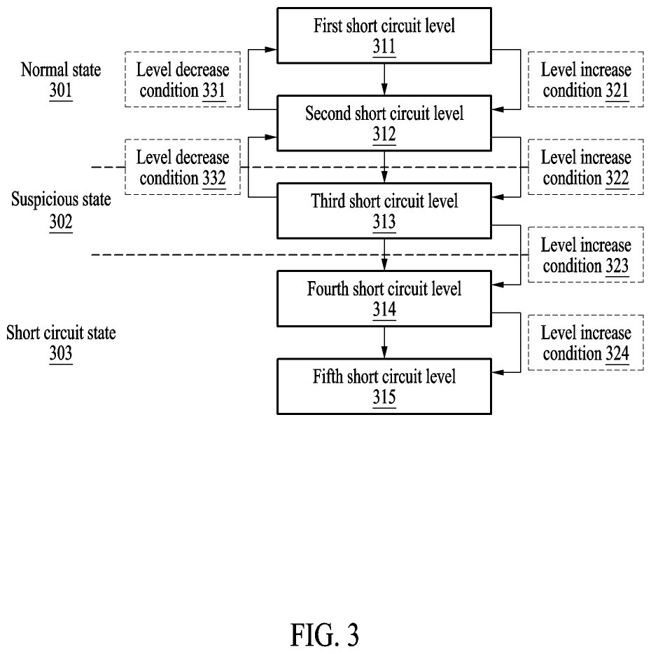

FIG. 3 illustrates short circuit levels according to one or more embodiments. In one embodiment, the short circuit detection may be performed in stages using five short circuit levels: a first short circuit level 311, a second short circuit level 312, a third short circuit level 313, a fourth short circuit level 314, and a fifth short circuit level 315. Although FIG. 3 illustrates five short circuit levels, this is merely one example, and the invention is not limited to exactly five levels.

The first through fifth short circuit levels 311 to 315 may be grouped into one of three states: a normal state 301 in which a battery operates normally without a short circuit, a suspicious state 302 in which a short circuit of the battery is suspected to occur, and a short circuit state 303 in which the short circuit of the battery is confirmed. In the illustrated example, the first and second short circuit levels 311 and 312 correspond to the normal state 301, the third short circuit level 313 corresponds to the suspicious state 302, and the fourth and fifth short circuit levels 314 and 315 correspond to the short circuit state 303. However, these assignments are flexible; for example, the second short circuit level 312 could alternatively be categorized within the suspicious state 302.

A current short circuit level may be determined based on a set of level increase conditions 321 to 324 and level decrease conditions 331 and 332. When the level increase conditions 321 to 324 are satisfied/met, among the first to fifth short circuit levels 311 to 315, the current short circuit level may be set as a higher level that is closer to the short circuit state 303 than the current short circuit level. For example, when the current short circuit level is the first short circuit level 311 and the level increase condition 321 is satisfied, the current short circuit level may be set as the second short circuit level 312. When the level decrease conditions 331 and 332 are satisfied/met, among the first to fifth short circuit levels 311 to 315, the current short circuit level may be set as a lower level that is closer to the normal state 301 than the current short circuit level. For example, when the current short circuit level is the third short circuit level 313 and the level decrease condition 332 is satisfied, the current short circuit level may be set as the second short circuit level 312.

The level decrease mechanism based on the level decrease conditions 331 and 332 may be limitedly applied to, among the first to fifth short circuit levels 311 to 315, the first to third short circuit levels 311 to 313 belonging to the normal state 301 and the suspicious state 302. When the current short circuit level reaches the fourth or fifth short circuit levels 314 and 315 of the short circuit state 303, the short circuit may already have occurred. In this case, since the possibility of thermal runaway or explosion increases, lowering the level may be restricted.

The level increase conditions 321 to 324 may be set based on a processed score and a corresponding threshold value. For example, the system may determine whether the level increase conditions 321 to 324 are satisfied/met by comparing the processed score with the corresponding threshold value. A predetermined section (e.g., an SOC section) may be considered in the level increase conditions 321 to 324. Detection scores may be accumulated so that an accumulated score may be determined or a moving average of the detection scores in a predetermined time section may be determined. The accumulated score and/or the moving average may serve as the processed score to be compared with the corresponding threshold value.

The first short circuit level 311 may represent a state in which no short circuit feature signals are detected. At this level, the accumulated score may be initialized to 0. For example, if a first short circuit feature signal is assigned a detection score of 1, a second short circuit feature signal is assigned 5, and a third short circuit feature signal is assigned 7 (values that are illustrative only), then when no short circuit feature signals are detected, the accumulated score remains 0, and the system maintains the first short circuit level 311. In this context, the first short circuit feature signal may be detected based on an average resistance error parameter, the second short circuit feature signal may be detected based on a charging/discharging error parameter and/or an accumulated SOC correction parameter, and the third short circuit feature signal may be detected based on an accumulated SOC correction difference parameter, but examples are not limited thereto. The average resistance error parameter, the charging/discharging error parameter, the accumulated SOC correction parameter, and the accumulated SOC correction difference parameter are described in detail below.

The second short circuit level 312 may represent a state in which a small number of short circuit feature signals are detected, resulting in the accumulated score not being 0. When the short circuit feature signals are detected, the current short circuit level may be set as the second short circuit level 312. The level increase condition 321 may include a condition in which the accumulated score is greater than 0. Since there may be a possibility that the short circuit feature signals may occur in a situation in which a short circuit does not exist, the second short circuit level 312 may be classified as the normal state 301. Alternatively, it may also be possible to place the second short circuit level 312 in the suspicious state 302.

The third short circuit level 313 may represent a state in which numerous short circuit feature signals are detected, causing the accumulated score to exceed a first threshold value. For example, the first threshold value may be 30,000 but is not limited thereto. When the accumulated score exceeds the first threshold value, the current short circuit level may be set as the third short circuit level 313. The level increase condition 322 may include a condition in which the accumulated score is greater than the first threshold value. Since numerous short circuit feature signals are detected, the third short circuit level 313 may belong to the suspicious state 302.

The fourth short circuit level 314 may represent a state in which there is an increased occurrence frequency of the short circuit feature signals. In this case, the moving average of the detection scores may exceed a second threshold value, thereby satisfying level increase condition 323. When the moving average of the detection scores exceeds the second threshold value, the current short circuit level may be set as the fourth short circuit level 314. The level increase condition 323 may include a condition in which the moving average of the detection scores is greater than the second threshold value. The time section for determining the moving average may be determined experimentally. Given the increased frequency of signal occurrence, the fourth short circuit level 314 may belong to the short circuit state 303.

The fifth short circuit level 315 may represent a state in which the occurrence frequency of the short circuit feature signals further increases, particularly in a specific section of interest (e.g., the section where an SOC is less than 80%). At this stage, either the moving average of the detection scores may exceed a third threshold value or the moving average of the detection scores in the section of interest may exceed a fourth threshold value. The level increase condition 324 may include a condition in which the moving average of the detection scores is greater than the third threshold value or a condition in which the moving average of the detection scores in the section of interest is greater than the fourth threshold value. The third threshold value may be greater than the fourth threshold value, and the fourth threshold value may be greater than the second threshold value. For example, the second threshold value may be 2, the third threshold value may be 4, and the fourth threshold value may be 3.5, but examples are not limited thereto.

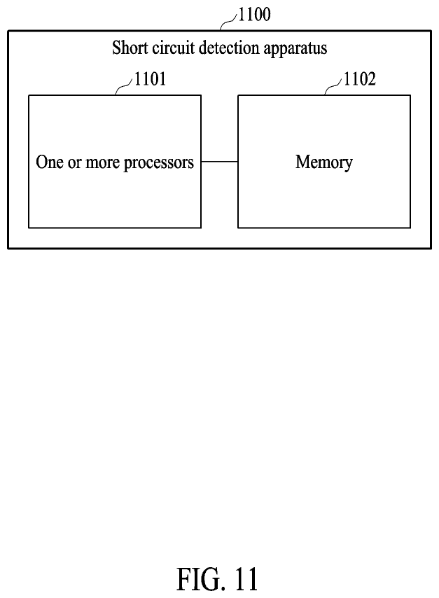

The fifth short circuit level 315 may indicate a more severe short circuit condition than the fourth short circuit level 314. When the current short circuit level reaches either the fourth short circuit level 314 or the fifth short circuit level 315, a short circuit detection apparatus (e.g., apparatus 120 in FIG. 1 or apparatus 1100 in FIG. 11) may definitively declare a short circuit and perform appropriate countermeasures, such as providing an alarm to notify the user.

The level decrease conditions 331 and 332 may be set based on the degree to which a stable state is maintained. The stable state may include a period during which additional short circuit feature signals are not detected. For example, when the additional short circuit feature signals are not detected, the detection scores may not be generated, or the accumulated score does not increase, the battery may be determined to be in a stable state. The degree to which the stable state is maintained may be determined based on the time and/or battery capacity. For example, the level decrease conditions 331 and 332 may include a condition in which the stable state is maintained for a duration exceeding a threshold and/or a condition in which the stable state is maintained while the battery capacity change exceeds the threshold value. For example, it may be required that the stable state be maintained until the battery driving capacity at the point of entering the stable state exceeds K times the battery capacity. For example, K may be 5 but is not limited thereto. The battery capacity may be measured based on its state of health (SOH).

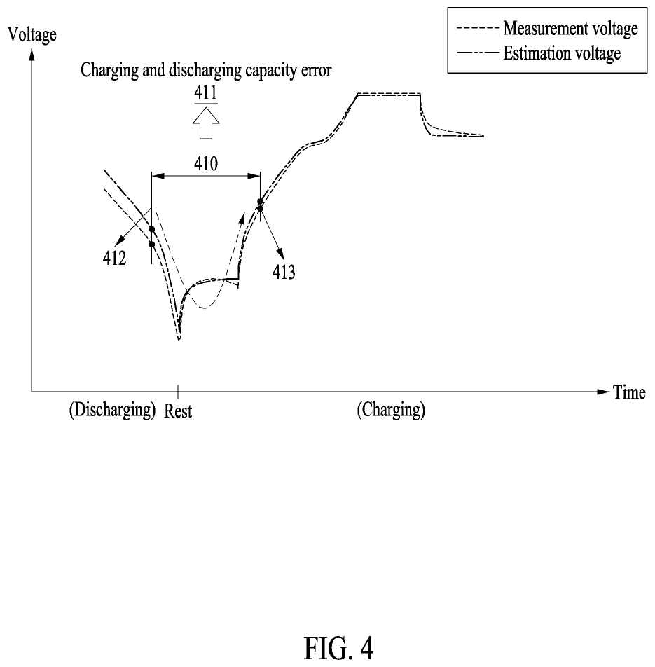

FIG. 4 illustrates an operation of determining a charging and discharging capacity error parameter according to one or more embodiments. Referring to FIG. 4, a charging and discharging capacity error 411, which is defined as the difference between a discharging capacity and a charging capacity, may be determined in a target section 410. This target section 410 may span from a start target point 412 in a discharging phase where a battery reaches a reference charging capacity, to an end target point 413 in a charging phase where the battery reaches the reference charging capacity again, after being discharged and charged. The charging and discharging capacity error parameter corresponding to the charging and discharging capacity error 411 may be used as a detection parameter.

The reference charging capacity may be determined, using a battery model, based on an estimated SOC and/or stoichiometry of an anode. For example, the reference charging capacity may be determined to be a charging capacity at a predetermined point within a section/range where the SOC and/or stoichiometry lies between 20% and 80%. For example, the reference charging capacity may be, but is not limited thereto, a charging capacity at a point where the SOC is 30%. Accordingly, the start target point 412 may correspond to a point where the SOC is 30% in the discharging section, and the end target point 413 may correspond to a point where the SOC is 30% in the charging section.

When the battery is in a normal state, the discharging capacity according to measurement voltage and the discharging capacity according to estimation voltage may be the same, and the charging capacity according to the measurement voltage and the charging capacity according to the estimation voltage may also be the same. However, when a battery cell is in a short circuit state (i.e., the battery cello experiences a short circuit), an error (e.g., a discrepancy) may occur between the discharging capacity according to the measurement voltage and the discharging capacity according to the estimation voltage. When the battery cell is in a short circuit state, an error (e.g., a discrepancy) may occur between the charging capacity according to the measurement voltage and the charging capacity according to the estimation voltage.

In the event of a short circuit within a battery cell of a battery, a voltage drop may occur during both the discharging and charging phases due to current leakage. When charging is performed in a short circuit state, the battery may require a higher current than in a normal state, resulting in a slower charging speed/rate than in the normal state. When discharging is performed, the battery may deliver the same discharging energy as in the normal state with a reduced current than in the normal state, thereby causing a faster discharging speed than in the normal state. Consequently, in the short circuit state, there can be a loss of power supplied to the battery for charging, which may lead to an increased charging capacity and a decreased discharging capacity compared to the normal state.

The charging and discharging capacity error 411 may be accumulated over the target section 410. For example, errors between the discharging capacity according to the measurement voltage and the discharging capacity according to the estimation voltage in the discharging section may be corrected using an error correction model. Correction values corresponding to the errors in the target section 410 may be continuously accumulated and applied periodically. This process reduces the difference between the measurement voltage and the estimation voltage in the target section 410 through ongoing error correction.

The charging and discharging capacity error 411 in the target section 410 may be determined based on the accumulated correction values from the start target point 412 to the end target point 413. A threshold value may be defined for the charging and discharging capacity error parameter corresponding to the charging and discharging capacity error 411. For example, the threshold value may be determined through experimental determination, which may take into account factors such as a battery capacity, an initial error of the battery model, a theoretical error of the size of a target short circuit to be detected, and the like. Among various threshold values, the threshold value for the charging and discharging capacity error parameter may be referred to as a corresponding threshold value of the charging and discharging capacity error parameter. Short circuit feature signals may be detected by comparing the charging and discharging capacity error parameter with the corresponding threshold value. For example, the short circuit feature signals may be detected when the charging and discharging capacity error parameter exceeds the corresponding threshold value.

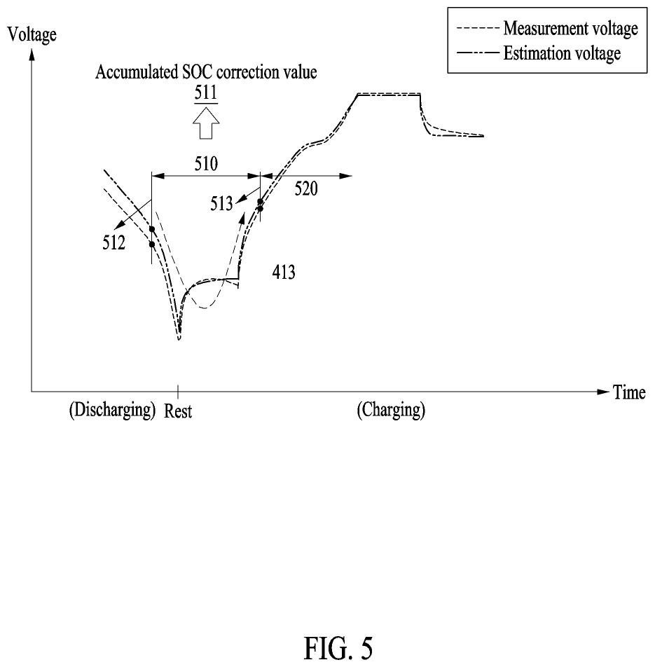

In addition to the charging and discharging capacity error 411, other parameters such as an SOC error, a voltage error, etc., may be used. As shown in FIG. 4, the short circuit feature signals may be detected at a predetermined detection section (e.g., a specific section following the end target point 413) rather than at a single predetermined detection point (e.g., the end target point 413). FIG. 5 provides an example in which the SOC error and the predetermined detection section are used.

FIG. 5 illustrates an operation of determining an accumulated SOC correction parameter according to one or more embodiments. Referring to FIG. 5, an accumulated SOC correction value 511 may be determined in a target section 510 between a start target point 512 in a discharging phase where a battery reaches a reference SOC and an end target point 513 in a charging section where the battery reaches the reference SOC again after being discharged and charged. When the battery is in a short circuit state, errors/discrepancies may occur between an SOC according to measurement voltage and an SOC according to estimation voltage, and these errors/discrepancies may be corrected using an error correction model. For example, the SOC according to estimation voltage may be corrected downward (e.g., in the negative direction) due to a voltage drop.

The error correction model may correct the errors using corresponding correction values. When the battery is in a short circuit state, continuous error correction may be performed and the correction values used for the continuous error correction may be accumulated. Thus, an SOC error may be continuously corrected in the target section 510, and the accumulated SOC correction value 511 may be determined based on the continuous SOC error correction. The accumulated SOC correction parameter corresponding to the accumulated SOC correction value 511 may be used as a detection parameter.

The reference SOC may be determined based on an estimated SOC using a battery model. For example, the reference SOC may be set to be a predetermined value within the range of 20% to 80%. For example, the reference SOC may be 30% but is not limited thereto. In this case, the start target point 512 may correspond to a point where the SOC is 30% in the discharging phase, and the end target point 513 may correspond to a point where the SOC is 30% in the charging phase.

A threshold value for the accumulated SOC error parameter corresponding to the accumulated SOC correction value 511 may be defined. For example, the threshold value may be determined through experimental determination. Factors such as a battery capacity, an initial error of the battery model, a theoretical error of the size of a target short circuit to be detected, and the like may be considered in determining the threshold value. Among various threshold values, the threshold value for the accumulated SOC error parameter may be referred to as a corresponding threshold value of the accumulated SOC error parameter. Short circuit feature signals may be detected by comparing the accumulated SOC error parameter with the corresponding threshold value. For example, the short circuit feature signals may be detected when the accumulated SOC error parameter exceeds the corresponding threshold value.

Unlike the example of FIG. 4 where the short circuit feature signals are detected at the predetermined detection point (e.g., the end target point 413 of FIG. 4), in FIG. 5, the short circuit feature signals may be detected over a detection section 520. In this configuration, the target section 510 may be referred to as a parameter determination section. The detection section 520 may be a predetermined section following the target section 510. For example, when an SOC at the end target point 513 in the target section 510 is 30%, the detection section 520 may be a section having an SOC range of 30% to 80%. When the battery is in a short circuit state, the short circuit feature signals may be continuously detected throughout the detection section 520.

Additionally, any remaining uncorrected voltage error in the target section 510 may be used to detect the short circuit feature signals. The voltage error may be converted into the SOC error using an open circuit voltage (OCV) table. At least a portion of the SOC error may be merged into the accumulated SOC correction value 511, and the short circuit feature signals may be detected by comparing the merge result with the threshold value.

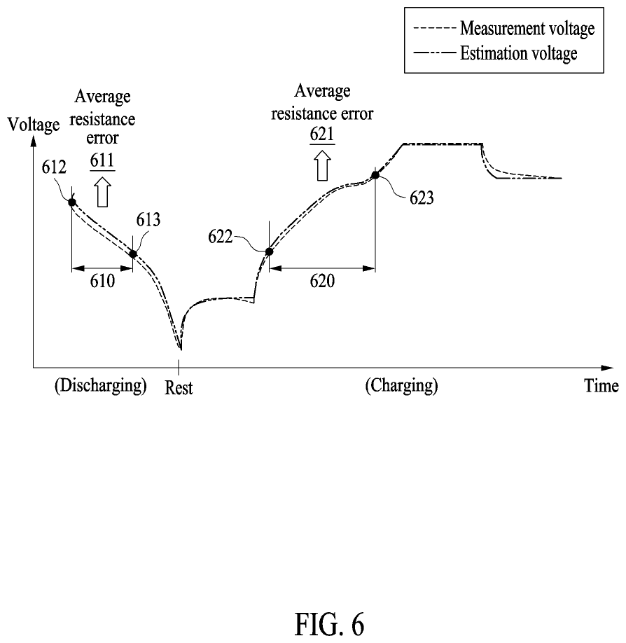

FIG. 6 illustrates an operation of determining an average resistance error parameter according to one or more embodiments.

When the actual state change of a battery, such as degradation, is reflected in voltage when estimating the voltage of the battery in a normal state, the resulting difference may correspond to a short circuit component of a measurement value. Here, the short circuit component may be expressed as the product of short circuit resistance and short circuit current. A short circuit detection apparatus (e.g., apparatus 120 in FIG. 1 or apparatus 1100 in FIG. 11), hereinafter referred to as ‘apparatus’, may detect a short circuit using a resistance error parameter based on the relationship in which the difference between measurement voltage and estimation voltage corresponds to the short circuit component.

Measurement data may include the measurement voltage and measurement current of the battery, and estimation data may include the estimation voltage of the battery. The apparatus may determine the resistance error parameter by determining the ratio between the measurement current and a voltage error corresponding to the difference between the measurement voltage and the estimation voltage.

The measurement data may include battery measurement values over a preset detection period, and the estimation data may include battery estimation values over the same period. The apparatus may determine resistance error values for the preset detection period based on the measurement values and the estimation values. The resistance error values may correspond to the resistance error parameter. The apparatus may modify the resistance error values by performing an operation based on the resistance error values. For example, an average, an accumulated value, a change rate, and the like of the resistance error values may be determined. For example, average resistance errors may be determined based on the average of the resistance error values.

Referring to FIG. 6, the resistance error values may be determined in a first target section 610 during the discharging phase, and an average resistance error 611 in the first target section 610 may be determined by averaging the resistance error values in the first target section 610. Similarly, during charging phase, the resistance error values may be determined in a second target section 620, and an average resistance error 621 in the second target section 620 may be determined by averaging the resistance error values in the second target section 620. An average resistance error difference parameter representing the difference between the average resistance errors 611 and 621 may be determined, and may be used as a detection parameter. For example, short circuit feature signals may be detected by comparing the average resistance error difference parameter with a corresponding threshold value.

The apparatus may set a target section based on an SOC level. For example, the apparatus may define the first target section 610 as a section in which discharging occurs from a first SOC level 612 to a second SOC level 613 and may define the second target section 620 as a section in which charging occurs from a third SOC level 622 to a fourth SOC level 623. The first SOC level 612 and the fourth SOC level 623, as well as the second SOC level 613 and the third SOC level 622, may be set to be the same or different. In addition, an interval between the first SOC level 612 and the second SOC level 613 and an interval between the third SOC level 622 and the fourth SOC level 623 may be set to be the same or different. As a non-limiting example, the first SOC level 612 may be 100%, the second SOC level 613 may be 50%, the third SOC level 622 may be 25%, and the fourth SOC level 623 may be 75%.

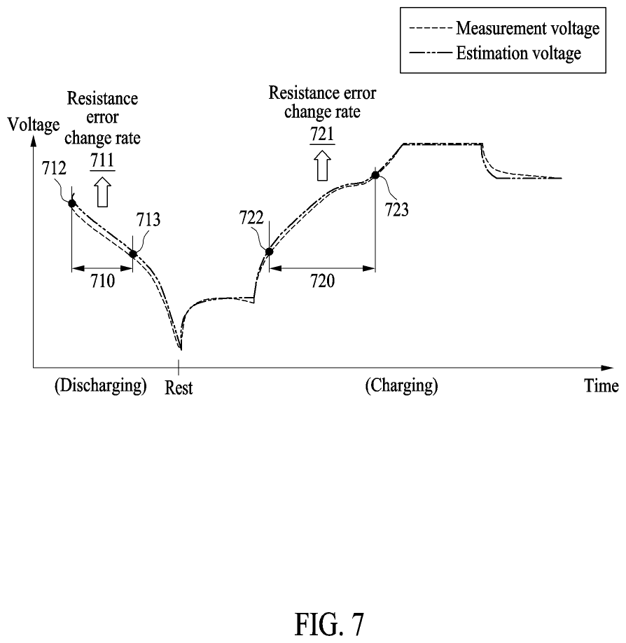

FIG. 7 illustrates an operation of determining a resistance error change rate parameter according to one or more embodiments. Referring to FIG. 7, based on resistance error values in a first target section 710 of a discharging phase, a short circuit detection apparatus (e.g., apparatus 120 in FIG. 1 or apparatus 1100 in FIG. 11) may determine a resistance error change rate parameter representing a resistance error change rate 711. Similarly, based on resistance error values in a second target section 720 of a charging phase, the apparatus may determine a resistance error change rate parameter representing a resistance error change rate 721.

The apparatus may determine a first resistance error change rate parameter based on the error increase rate of the resistance error values in the first target section 710 and may determine a second resistance error change rate parameter based on the error decrease rate of the resistance error values in the second target section 720. The first and second resistance error change rate parameters may be determined according to the change rate determined over a preset number of detection periods, and may be used as detection parameters. For example, the apparatus may detect a first short circuit feature signal by comparing the first resistance error change rate parameter with its corresponding threshold value and may detect a second short circuit feature signal by comparing the second resistance error change rate parameter with its corresponding threshold value.

The first target section 710 and the second target section 720 may be defined based on an SOC levels. As non-limiting examples, a first SOC level 712 may be 100%, a second SOC level 713 may be 50%, a third SOC level 722 may be 25%, and a fourth SOC level 723 may be 75%.

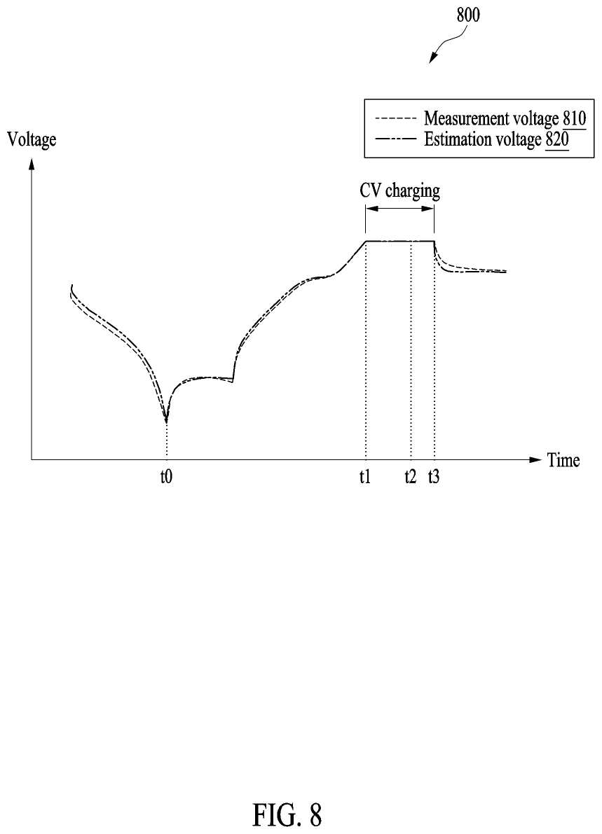

FIG. 8 illustrates an operation of determining an accumulated SOC correction difference parameter in a constant voltage (CV) charging section according to one or more embodiments. Referring to FIG. 8, in a graph 800, a first curve 810 may represent measurement voltage and a second curve 820 may represent estimation voltage. A point t0 may represent a discharging endpoint of a battery (e.g., the battery 110 in FIG. 1), and a point t3 may represent a charging endpoint of the battery. The battery may transition into a charging state through a rest state after the point t0 or may enter the rest state after the point t3. The battery may not be charged or discharged in the rest state. There may be no current flow in the rest state.

Before a point t1 in the charging section, constant current (CC) charging may be performed. Once the battery voltage reaches a level required for CV charging at the point t1, CV charging may be performed during a charging section from the point t1 to the point t3. During the discharging and charging processes depicted in the graph 800, the difference may occur between the first curve 810 according to the measurement voltage and the second curve 820 according to the estimation voltage; however, continuous error correction may serve to narrow the difference.

The accumulated SOC correction difference parameter, which represents the difference between accumulated SOC correction values at designated target points in the CV charging section, may be used as a detection parameter. For example, the target points may be selected from the points t1, t2, and t3. The difference between the accumulated correction values may correspond to the difference between a first accumulated correction value at the point t1 and a second accumulated correction value at the point t2 or may correspond to the difference between the first accumulated correction value at the point t1 and a third accumulated correction value at the point t3. A short circuit detection apparatus (e.g., apparatus 120 in FIG. 1 or apparatus 1100 in FIG. 11) may detect short circuit feature signals by comparing the accumulated SOC correction difference parameter with a corresponding threshold value.

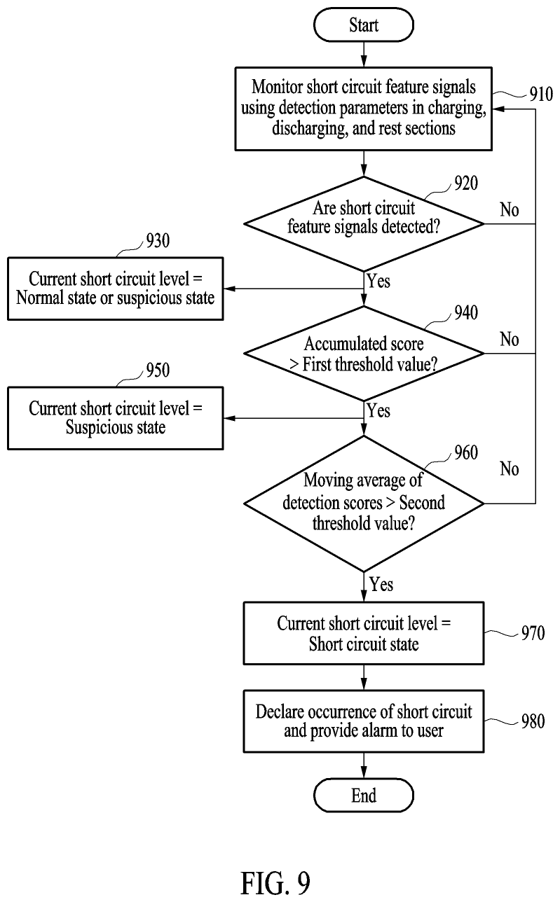

FIG. 9 illustrates an operation of adjusting a current short circuit level according to one or more embodiments. Referring to FIG. 9, in operation 910, a short circuit detection apparatus (e.g., apparatus 120 in FIG. 1 or apparatus 1100 in FIG. 11) may monitor short circuit feature signals using detection parameters from charging, discharging, and rest sections. The apparatus may determine the detection parameters using data collected during the battery operation along with a battery model, and may attempt to detect the short circuit feature signals using the detection parameters.

In operation 920, the apparatus may determine whether the short circuit feature signals have been detected. When no such signals are detected, operation 910 may be performed again. When the short circuit feature signals are detected, in operation 930, the apparatus may set a current short circuit level to either a normal state or a suspicious state. At this point, the apparatus may also determine a processed score by processing detection scores assigned to the short circuit feature signals. For example, the processed score may include at least one of an accumulated score of the detection scores or a moving average of the detection scores.

In operation 940, the apparatus may determine whether the accumulated score exceeds a first threshold value. When the accumulated score does not exceed the first threshold value, operation 910 may be performed again. When the accumulated score exceeds the first threshold value, in operation 950, the apparatus may set the current short circuit level to a suspicious state. The apparatus may continue to accumulate the detection scores of the short circuit feature signals throughout this process.

In operation 960, the apparatus may determine whether the moving average of the detection scores exceeds a second threshold value. When the moving average of the detection scores does not exceed the second threshold value, operation 910 may be performed again. When the moving average of the detection score exceeds the second threshold value, in operation 970, the apparatus may set the current short circuit level to a short circuit state. In operation 980, the apparatus may declare the occurrence of a short circuit and provide an alarm to the user.

Each state of a normal state, a suspicious state, or a short circuit state may be divided into multiple short circuit levels. Detailed threshold values may be used for the state classification. The detection scores may be processed into an accumulated value, an average value, a moving average value, etc., and detailed short circuit determination may be performed using the processed data and the detailed threshold values. The threshold values may be determined experimentally, and take into account factors such as the size of a short circuit to be detected. The apparatus may output a current state as a short circuit detection result, which may be expressed as a normal state, a suspicious state, or a short circuit state. The apparatus may express the intensity of a short circuit based on the short circuit possibility and/or the magnitude of short circuit resistance in various forms, such as numerical values, in the short circuit detection result.

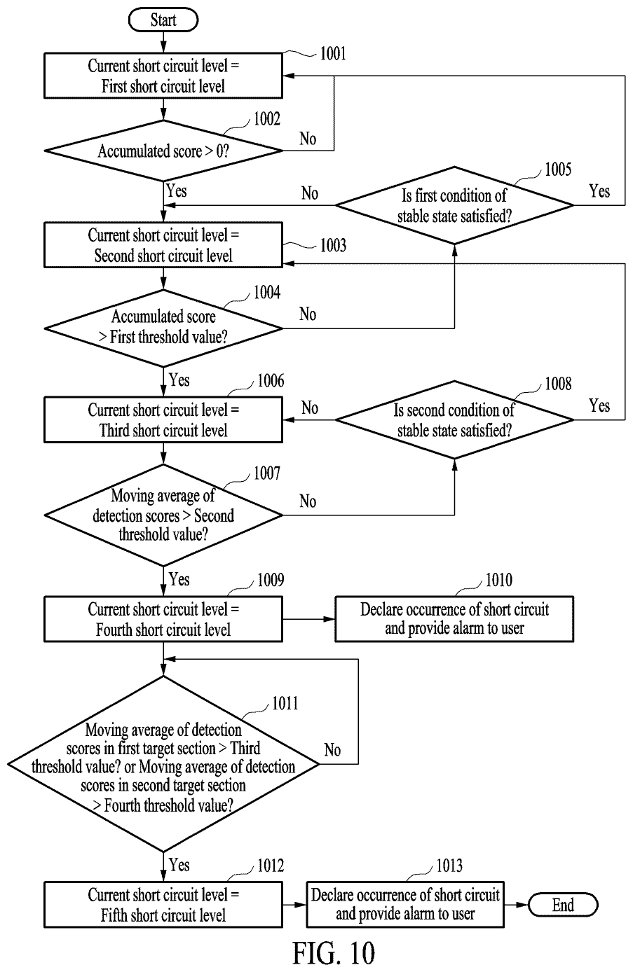

FIG. 10 illustrates another operation of adjusting a current short circuit level according to one or more embodiments. Referring to FIG. 10, in operation 1001, a short circuit detection model (hereinafter referred to as ‘detection model’) may initially set a current short circuit level as a first short circuit level, which corresponds to a normal state. In the short circuit detection procedure, the current short circuit level may start from the first short circuit level.

In operation 1002, the detection model may determine whether an accumulated score is greater than 0. The detection model may determine detection parameters using measurement data and estimation data, detect short circuit feature signals based on the detection parameters, and determine an accumulated score by summing detection scores of the short circuit feature signals. In the short circuit detection procedure, the accumulated score may be initialized to 0, and remain at 0 until the short circuit feature signals are detected. When the short circuit feature signals are detected, the accumulated score may exceed 0. When the accumulated score is not greater than 0, the apparatus may return to operation 1001. When the accumulated score is greater than 0, the apparatus may perform operation 1003.

In operation 1003, the apparatus may set the current short circuit level to a second short circuit level. As shown in FIG. 3, the second short circuit level may correspond to a normal state. The short circuit feature signals may be detected momentarily in at least one point due to an SOC estimation error, an SOH estimation error, a sensing error, etc. Considering this situation, the second short circuit level may be classified as a normal state. Alternatively, the second short circuit level may also be classified as a suspicious state. There may be a high likelihood of an error occurring in the initial operation of a battery model. A limitation condition may be set to allow an increase in the current short circuit level when a cycle count determined based on the charging and discharging capacity exceeds a predetermined level or when the detected short circuit feature signals reach a predetermined level (e.g., when a sum of the detected short circuit feature signals reach the predetermined level).

In operation 1004, the apparatus may determine whether the accumulated score is greater than a first threshold value. When the accumulated score is greater than the first threshold value, in operation 1006, the apparatus may set the current short circuit level to a third short circuit level. Exceeding the first threshold value may indicate that the short circuit feature signals are occurring continuously. As shown in FIG. 3, the third short circuit level may be classified as a suspicious state. The first threshold value may be determined experimentally.

The apparatus may use a moving average of the detection scores to facilitate rapid transition from a suspicious state to a short circuit state. Since the more severe the degree of a short circuit, the more quickly the short circuit needs to be determined, the moving average of the detection scores may be used to quickly detect the short circuit state when the short circuit feature signals are occurring continuously. The moving average ratio may be set based on a data acquisition interval and/or a model determination interval. For example, at each time step during which the battery model is determined, a new detection score may be incorporated into the existing moving average value at a predetermined ratio (e.g., 99:1). For example, a new moving average value may be determined by adding the new detection score to the existing moving average value.

In operation 1007, the apparatus may determine whether the moving average of the detection scores is greater than a second threshold value. When the moving average of the detection scores is greater than the second threshold value, in operation 1009, the apparatus may set the current short circuit level to a fourth short circuit level, which, as shown in FIG. 3, may correspond to a short circuit state. The second threshold value may be determined experimentally. In operation 1010, the apparatus may declare the occurrence of a short circuit and issue an alarm to the user.

In operation 1011, the apparatus may determine whether the moving average of the detection scores in a first target section exceeds a third threshold value or whether the moving average of the detection scores in a second target section exceeds a fourth threshold value. For example, the second target section may be narrower than the first target section, and the fourth threshold value may be less than the third threshold value. For example, the first target section may encompass the entire SOC range, and the second target section may be limited to SOC values below 80%. The third and fourth threshold values may be determined experimentally. The fourth threshold value may be greater than the second threshold value. As a non-limiting example, the second threshold value may be 2, the third threshold value may be 4, and the fourth threshold value may be 3.5.

When the moving average of the detection scores in the first target section exceeds the third threshold value or the moving average of the detection scores in the second target section exceeds the fourth threshold value, in operation 1012, the apparatus may set the current short circuit level to a fifth short circuit level, which as shown in FIG. 3, corresponds to a short circuit state. In operation 1013, the apparatus may declare the occurrence of a short circuit and provide an alarm to the user.

The fourth short circuit level may be distinguished from the fifth short circuit level based on the severity of the short circuit. For example, the fourth short circuit level may indicate a soft short circuit, whereas the fifth short circuit level may indicate a hard short circuit. Consequently, the short circuit occurrence declaration and the type of alarm may differ, with a stronger alert issued at the fifth short circuit level compared to the fourth short circuit level.

A rollback function may be provided as necessary to lower the current short circuit level. The rollback function may be provided in a normal state and/or a suspicious state but not in a short circuit state. The current short circuit level may revert to a suspicious state when a temporary sensing error or estimation error occurs or when the short circuit feature signals accumulate gradually over an extended period. In this case, the battery may again exhibit a normal state for a prolonged period.

In operation 1005, the apparatus mat determine whether a first condition of a stable state is satisfied. The stable state may include a state in which no additional short circuit feature signals are detected. For example, the battery may be determined to be in a stable state when no short circuit feature signals are detected, no detection scores are generated, or the accumulated score does not increase. The degree to which the stable state is maintained may be determined based on elapsed time and/or battery capacity. For example, the first condition may require that the stable state is maintained for a time period exceeding a threshold value and/or maintained while the battery capacity change exceeds the threshold value. For example, it may be required that the stable state be maintained until the battery driving capacity at the point of entering the stable state exceeds the battery capacity by a factor of K (e.g., K may be 5, though this is not limiting). The battery capacity may be measured based on an SOH. When the first condition of the stable state is satisfied, in operation 1001, the apparatus may set the current short circuit level as the first short circuit level. When a rollback is performed, the accumulated score may be initialized. For example, the accumulated score may be initialized to the minimum value (e.g., 0) corresponding to the first short circuit level.

In operation 1008, the apparatus may determine whether a second condition of a stable state is satisfied. The second condition may be the same as or different from the first condition. For example, the second condition may be more rigid than the first condition. For example, the second condition may require a larger time threshold and/or a larger K value than the first condition. When the second condition of the stable state is satisfied, in operation 1003, the apparatus may set the current short circuit level to a second short circuit level. When a rollback is performed, the accumulated score may be initialized. For example, the accumulated score may be initialized to the minimum value (e.g., 1) corresponding to the second short circuit level.

FIG. 11 illustrates a configuration of a short circuit detection apparatus according to one or more embodiments. Referring to FIG. 11, a short circuit detection apparatus 1100 (hereinafter referred to as ‘apparatus 1100’) may include one or more processors 1101 and a memory 1102. The memory 1102 may be connected to the one or more processors 1101 and store instructions (e.g., executable code) executable by the one or more processors 1101, data to be processed by the one or more processors 1101, or data that has been processed by the one or more processors 1101. The memory 1102 may include a non-transitory computer-readable medium such as high-speed random-access memory (RAM) and/or a non-volatile computer-readable storage medium (e.g., at least one disk storage device, a flash memory device, or other non-volatile solid-state memory devices).

The one or more processors 1101 may be respectively configured as processing circuitry to execute instructions to perform the operations described with reference to FIGS. 1 through 10, FIG. 12, and FIG. 13. For example, the one or more processors 1101 may generate measurement data by measuring a state of a battery, generate estimation data regarding the state of the battery using a battery model that simulates the battery, determine detection parameters to detect a short circuit of the battery using the measurement data and the estimation data, detect short circuit feature signals based on the detection parameters, determine a processed score by processing detection scores assigned to the short circuit feature signals based on the types of the short circuit feature signals, and determine a current short circuit level among short circuit levels based on the processed score. The processed score may include at least one of an accumulated score of the detection scores or a moving average of the detection scores. In addition, the description provided with reference to FIGS. 1 through 10, FIG. 12, and FIG. 13 may be applicable to the apparatus 1100.

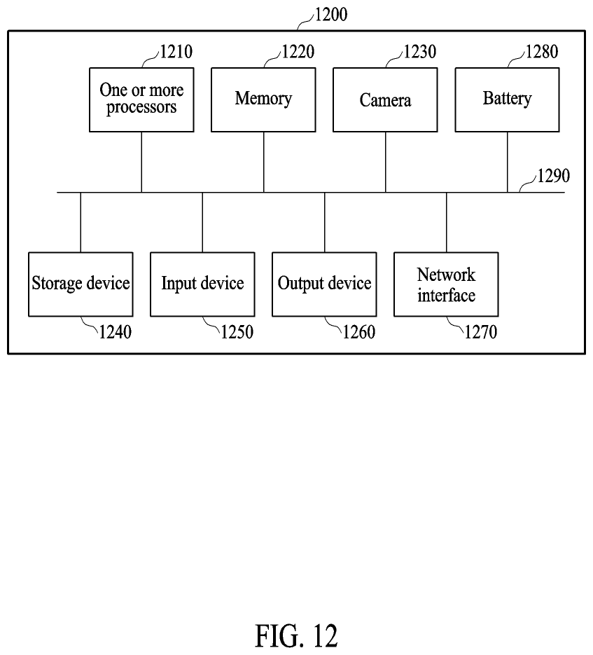

FIG. 12 illustrates a configuration of an electronic device according to one or more embodiments. Referring to FIG. 12, an electronic device 1200 may include one or more processors 1210, a memory 1220, a camera 1230, a storage device 1240, an input device 1250, an output device 1260, a network interface 1270, and a battery 1280. These components may communicate with each other via a communication bus 1290. For example, the electronic device 1200 may be implemented as at least part of a mobile device (e.g., mobile phone, smartphone, PDA, netbook, tablet computer, or laptop computer), a wearable device (e.g., smartwatch, smart band, or smart glasses), a computing device (e.g., desktop, or server), a home appliance (e.g., TV, smart TV, or refrigerator), a security device (e.g., a door lock), or a vehicle (e.g., an autonomous vehicle or smart vehicle). The electronic device 1200 may structurally and/or functionally include the apparatus 120 of FIG. 1 and/or the apparatus 1100 of FIG. 11.

The one or more processors 1210 may be respectively configured as processing circuitry to execute instructions (e.g., executable code) or functions to be executed in the electronic device 1200. For example, the one or more processors 1210 may process the instructions stored in the memory 1220 or the storage device 1240. The one or more processors 1210 may perform the operations described with reference to FIGS. 1 through 11 and FIG. 13. The memory 1220 may include a non-transitory computer-readable storage medium or a non-transitory computer-readable storage device. The memory 1220 may store instructions to be executed by the one or more processors 1210 and may store related information while software and/or applications is executed by the electronic device 1200.

The camera 1230 may capture a photo and/or a video. For example, the camera 1230 may capture a face image including a user's face. The camera 1230 may be a three-dimensional (3D) camera that provides depth information associated with objects. The storage device 1240 may include a non-transitory computer-readable storage medium or a non-transitory computer-readable storage device. The storage device 1240 may store a greater quantity of information than the memory 1220 over an extended period. For example, the storage device 1240 may include a magnetic hard disk, an optical disc, flash memory, a floppy disk, or other non-volatile memories known in the art.

The input device 1250 may receive user input via traditional methods (e.g., keyboard and mouse) as well as new methods (e.g., touch input, voice input, or image input). For example, the input device 1250 may include a keyboard, a mouse, a touch screen, a microphone, or any other device that detects user input and transmits the detected input to the electronic device 1200. The output device 1260 may provide output from the electronic device 1200 to the user via visual, auditory, or haptic channels (e.g., a display, touch screen, speaker, or vibration generator). The network interface 1270 may communicate with external devices via wired or wireless networks. The battery 1280 may store and supply power to the electronic device 1200.

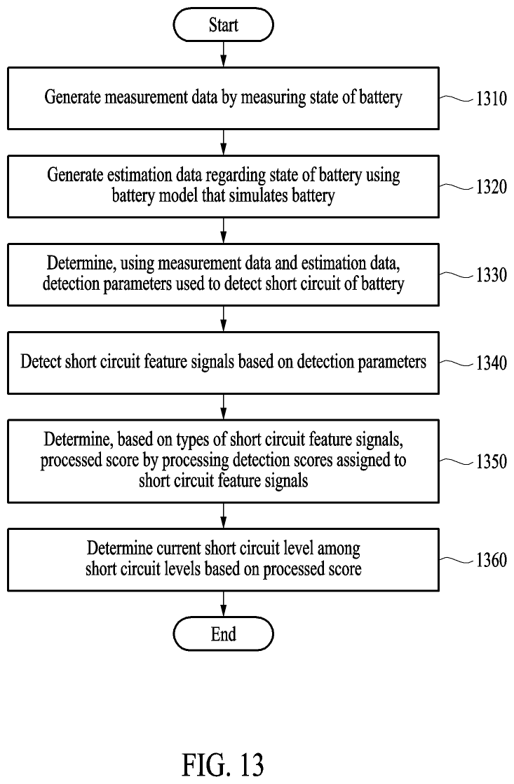

FIG. 13 illustrates a short circuit detection method according to one or more embodiments. Referring to FIG. 13, in operation 1310, a short circuit detection apparatus (e.g., apparatus 120/1100) may generate measurement data by measuring a state of a battery. In operation 1320, the apparatus may generate estimation data regarding the state of the battery using a battery model that simulates the battery. In operation 1330, the apparatus may determine, using the measurement data and the estimation data, detection parameters to detect a short circuit of the battery. In operation 1340, the apparatus may detect short circuit feature signals based on the detection parameters. In operation 1350, the apparatus may determine, based on the types of the short circuit feature signals, a processed score by processing detection scores assigned to the short circuit feature signals. In operation 1360, the apparatus may determine a current short circuit level among short circuit levels based on the processed score. The processed score may include at least one of an accumulated score of the detection scores or a moving average of the detection scores.

Among the short circuit feature signals, different detection scores may be assigned to different types of short circuit feature signals. The different detection scores may be set based on at least one of the sensitivity to the short circuit and the potential impact/influence of the various short circuit feature signals.

The current short circuit level may be adjusted, among the available short circuit levels, increasing to a higher level (closer to a short circuit state) when a level increase condition is met.

The level increase condition may be defined based on the accumulated score and a corresponding threshold value.

The current short circuit level may be decreased, among the available short circuit levels, to a lower level (closer to a normal state) when a level decrease condition is met.

The level decrease condition may be set based on the degree to which a stable state is maintained.

The stable state may be defined as a state in which no additional short circuit feature signals are detected.

Each of the short circuit levels may belong to one of three categories: a normal state in which the battery operates normally without a short circuit, a suspicious state in which the short circuit of the battery is suspected to occur, and a short circuit state in which the short circuit of the battery has occurred. The level decrease based on the level decrease condition may be limitedly applied to levels within the normal or suspicious state.

The detection parameters may include a charging and discharging capacity error parameter, which represents the difference between a discharging capacity and a charging capacity in a first target section between a first target point in a discharging section where the battery has a reference charging capacity and a second target point in a charging section where the battery has the reference charging capacity again after being discharged and charged. The short circuit feature signals may include a first short circuit feature signal generated based on the comparison result between a charging and discharging capacity error parameter and a corresponding threshold value.

The detection parameters may include an accumulated SOC correction parameter, which represents an accumulated SOC correction value in a second target section between a third target point in a discharging section where the battery has a reference SOC and a fourth target point in a charging section where the battery has the reference SOC again after being discharged and charged. The short circuit feature signals may include a second short circuit feature signal generated based on the comparison result between the accumulated SOC correction parameter and a corresponding threshold value.

The measurement data may include measurement voltage and measurement current. The estimation data may include estimation voltage. The detection parameters may include a resistance error parameter representing the ratio between the measurement current and a voltage error corresponding to the difference between the measurement voltage and the estimation voltage and an average resistance error difference parameter representing the difference between a first average resistance error of a third target section in a discharging section and a second average resistance error of a fourth target section in a charging section. The short circuit feature signals may include a third short circuit feature signal generated based on the comparison result between the average resistance error difference parameter and a corresponding threshold value.

The detection parameters may include an accumulated SOC correction difference parameter representing the difference between accumulated SOC correction values of target points in a CV charging section. The short circuit feature signals may include a fourth short circuit feature signal generated based on the comparison result between the accumulated SOC correction difference parameter and a corresponding threshold value.

The apparatuses, electronic devices, processors, memories, storage devices, batteries, cameras, storage devices, input devices, output devices, network interfaces, communication buses, battery 110, apparatus 120, apparatus 1100, one or more processors 1101, memory 1102, electronic device 1200, one or more processors 1210, memory 1220, camera 1230, storage device 1240, input device 1250, output device 1260, network interface 1270, battery 1280, communication bus 1290, and other apparatuses, devices, models, and components described herein with respect to FIGS. 1-13 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-13 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A processor-implemented method comprising:
generating measurement data by measuring a state of a battery;
generating estimation data regarding the state of the battery using a battery model that simulates the battery;
determining, using the measurement data and the estimation data, detection parameters for detecting a short circuit in the battery;
detecting short circuit feature signals based on the detection parameters;
determining a processed score by processing detection scores assigned to the short circuit feature signals according to types of the short circuit feature signals; and
determining a current short circuit level among multiple predefined short circuit levels based on the processed score.

2. The method of claim 1, wherein the processed score comprises either one or both of an accumulated score of the detection scores and a moving average of the detection scores.

3. The method of claim 1, wherein different detection scores are assigned to different types of the short circuit feature signals,
wherein the different detection scores are set based on either one or both of sensitivity of the battery to the short circuit and an influence of the respective short circuit feature signal on the short circuit.

4. The method of claim 1, further comprising setting the current short circuit level to a higher level that is closer to a confirmed short circuit state, when a level increase condition is satisfied.

5. The method of claim 4, wherein the level increase condition is set based on the processed score exceeding a corresponding threshold value.

6. The method of claim 1, further comprising setting the current short circuit level to a lower level that is closer to a normal state when a level decrease condition is satisfied.

7. The method of claim 6, wherein the level decrease condition is set based on a degree to which a stable state is maintained by the battery.

8. The method of claim 7, wherein the stable state is defined as a state in which no additional short circuit feature signals are detected over a predetermined period.

9. The method of claim 6, wherein each of the short circuit levels is associated with one of three states, comprising a normal state in which the battery operates without the short circuit, a suspicious state in which the short circuit is suspected to occur, and a short circuit state indicating that the short circuit is confirmed,
wherein the level decrease condition is applied only to levels corresponding to the normal and suspicious states.

10. The method of claim 1, wherein the detection parameters comprise a charging and discharging capacity error parameter representing a difference between a discharging capacity and a charging capacity measured over a first target section, spanning from a first target point in a discharging phase where the battery reaches a reference charging capacity to a second target point in a charging phase where the battery reaches the reference charging capacity again,
wherein the short circuit feature signals comprise a first short circuit feature signal generated by comparing the charging and discharging capacity error parameter with a corresponding threshold value.

11. The method of claim 1, wherein the detection parameters comprise an accumulated state of charge (SOC) correction parameter representing an accumulated SOC correction value in a second target section between a third target point in a discharging phase where the battery reaches a reference SOC and a fourth target point in a charging phase where the battery reaches the reference SOC again,
wherein the short circuit feature signals comprise a second short circuit feature signal generated by comparing the accumulated SOC correction parameter with a corresponding threshold value.

12. The method of claim 1, wherein
the measurement data comprises a measurement voltage and a measurement current,
the estimation data comprises an estimation voltage, and
wherein the detection parameters comprise a resistance error parameter representing a ratio between the measurement current and a voltage error corresponding to a difference between the measurement voltage and the estimation voltage, and an average resistance error difference parameter representing a difference between a first average resistance error of a third target section in a discharging phase and a second average resistance error of a fourth target section in a charging phase, and
wherein the short circuit feature signals comprise a third short circuit feature signal generated by comparing the average resistance error difference parameter with a corresponding threshold value.

13. The method of claim 1, wherein the detection parameters comprise an accumulated state of charge (SOC) correction difference parameter representing a difference between accumulated SOC correction values of target points in a constant voltage (CV) charging section,
wherein the short circuit feature signals comprise a fourth short circuit feature signal generated by comparing the accumulated SOC correction difference parameter with a corresponding threshold value.

14. An apparatus comprising:
one or more processors respectively comprising processing circuitry; and
a memory storing executable code, which upon execution by the one or more processors, configures the one or more processors to:
generate measurement data by measuring a state of a battery;
generate estimation data regarding the state of the battery using a battery model that simulates the battery;
determine, using the measurement data and the estimation data, detection parameters for detecting a short circuit of the battery;
detect short circuit feature signals based on the detection parameters;
determine a processed score by processing detection scores assigned to the short circuit feature signals according to types of the short circuit feature signals; and
determine a current short circuit level among multiple predefined short circuit levels based on the processed score.

15. The apparatus of claim 14, wherein the processed score comprises either one or both of an accumulated score of the detection scores and a moving average of the detection scores.

16. The apparatus of claim 14, wherein different detection scores are assigned to different types of short circuit feature signals,
wherein the different detection scores are set based on either one or both of sensitivity of the battery to the short circuit and an influence of the respective short circuit feature signal on the short circuit.

17. The apparatus of claim 14, wherein the one or more processors are further configured to set the current short circuit level to a higher level that is closer to a short circuit state when a level increase condition is satisfied.

18. The apparatus of claim 17, wherein the level increase condition is set based on the processed score exceeding a corresponding threshold value.

19. The apparatus of claim 14, wherein the one or more processors are further configured to set the current short circuit level to a lower level that is closer to a normal state when a level decrease condition is satisfied,
wherein the level decrease condition is set based on a degree to which a stable state is maintained by the battery.

20. An electronic device comprising:
a battery configured to supply power to the electronic device; and
one or more processors,
wherein the one or more processors are configured to:
generate measurement data by measuring a state of the battery;
generate estimation data regarding the state of the battery using a battery model that simulates the battery;
determine, using the measurement data and the estimation data, detection parameters for detecting a short circuit of the battery;
detect short circuit feature signals based on the detection parameters;
determine a processed score by processing detection scores assigned to the short circuit feature signals according to types of the short circuit feature signals; and
determine a current short circuit level among multiple predefined short circuit levels based on the processed score.
